(19) United States
(12) Patent Application Publication
(10) Pub. No.: US 2026/0344214 A1
(43) Pub. Date: Oct. 29, 2026

(54) DISPLAY DEVICE, METHOD OF MANUFACTURING DISPLAY DEVICE, AND ELECTRONIC DEVICE INCLUDING DISPLAY DEVICE

(71) Applicant: Samsung Display Co., Ltd., Yongin-si (KR)

(72) Inventors: Han Bit KIM, Yongin-si (KR); Mee Jae Kang, Yongin-si (KR); Yun Jung Oh, Yongin-si (KR); Do Kyeong Lee, Yongin-si (KR); Ki Seok Choi, Yongin-si (KR); Sang Gun Choi, Yongin-si (KR)

(73) Assignee: Samsung Display Co., Ltd., Yongin-si (KR)

(21) Appl. No.: 19/541,985

(22) Filed: Feb. 17, 2026

(30) Foreign Application Priority Data
Apr. 28, 2025 (KR) 10-2025-0055539

(51) Int. Cl. H10K 59/131; H10D 30/67; H10D 86/60

(52) U.S. Cl. CPC H10K 59/131; H10D 30/6713; H10D 30/6715; H10D 86/60

(57) ABSTRACT

The display device includes: an active layer on a base layer, the active layer including a source region, a drain region, and a channel region; a cover layer above the active layer; and a gate layer above the channel region, wherein the drain region comprises a first region overlapped by the cover layer and a second region not overlapped by the cover layer, in plan view, and wherein the first region has a lower dopant concentration than the second region.

### CROSS-REFERENCE TO RELATED APPLICATION

This application claims priority to and benefits of Korean Patent Application Number 10-2025-0055539 filed on Apr. 28, 2025, and all the benefits accruing therefrom under 35 U.S.C. §119, the disclosure of which is incorporated herein in its entirety by reference.

### BACKGROUND

### 1. Technical Field

The disclosure relates to a display device, a method of manufacturing the display device, and an electronic device including the display device.

### 2. Description of Related Art

Recently, due to the increasing interest in information display, research and development on display devices have been continuously conducted.

A display device includes circuit elements such as transistors. If leakage current is generated in these circuit elements, a display quality of the display device may be negatively affected.

For example, when leakage current occurs in some of the transistors, signal interference (e.g., crosstalk) between the circuit elements may increase, resulting in unintended effects to images displayed on the display device. For example, gradation or distorted images may be displayed, which may reduce display reliability.

### SUMMARY

An aspect of the disclosure provides a display device, a method of manufacturing the display device, and an electronic device including the display device, in which the possibility of leakage current occurring can be reduced and the risk of display quality being impaired due to the leakage current can be reduced.

An aspect of the disclosure provides a display device, a method of manufacturing the display device, and an electronic device including the display device that can improve display quality.

According to one or more embodiments of the disclosure, a display device may include: an active layer on a base layer, the active layer including a source region, a drain region, and a channel region; a cover layer above the active layer; and a gate layer above the channel region, wherein the drain region comprises a first region overlapped by the cover layer and a second region not overlapped by the cover layer, in plan view, and wherein the first region has a lower dopant concentration than the second region.

The cover layer may include a material that is permeable to a dopant doped into the drain region.

The cover layer may include an amorphous silicon material.

The cover layer may be formed across the first region and the channel region in plan view.

The cover layer may overlap the first region entirely in plan view.

The cover layer may have a floating state.

The cover layer may have an isolated shape.

The cover layer may have a polygonal shape or a shape with a curvature.

The cover layer may further include: a first gate insulating layer on the active layer; and a second gate insulating layer on the cover layer and the first gate insulating layer, wherein the cover layer may have a thickness less than the first gate insulating layer and the second gate insulating layer, and may have a thickness of 10 Å to 1000 Å.

The second region may be formed at a side of the first region, and the channel region may be formed at another side of the first region.

The cover layer may not overlap the source region in plan view.

The cover layer may be disposed across the drain region, the channel region, and the source region in plan view, and the source region may include a third region overlapped by the cover layer and a fourth region not overlapped by the cover layer, in plan view.

The cover layer may include a first cover layer overlapping the first region and a second cover layer overlapping the source region in plan view.

The source region may include a third region overlapped by the second cover layer and a fourth region not overlapped by the second cover layer, in plan view, and the third region may have a lower dopant concentration than the fourth region.

According to one or more embodiments of the disclosure, a method of manufacturing a display device may include: patterning a base active layer on a base layer; patterning a cover layer above the base active layer; patterning a gate layer above the base active layer and the cover layer; and obtaining an active layer by forming a source region, a drain region, and a channel region on the base active layer, wherein the cover layer included an amorphous silicon material.

The obtaining the active layer may include performing a doping process on the base active layer, and the performing the doping process may include forming a first region in the drain region overlapped by the cover layer.

The patterning the cover layer may include patterning the cover layer at a location below which the first region is formed.

The patterning the cover layer may include patterning the cover layer across an area below which the source region, the channel region, and the drain region are formed, in plan view.

The patterning the cover layer may include patterning a first cover layer overlapping the drain region and a second cover layer overlapping the source region in plan view.

According to one or more embodiments of the disclosure, an electronic device may include a processor, a display module electrically connected to the processor, the display module including the above display device; and a power module providing power to the display module.

### BRIEF DESCRIPTION OF DRAWINGS

The above and other features of embodiments of the invention will become more apparent by describing in further detail embodiments thereof with reference to the accompanying drawings, in which:

FIG. 1 is a schematic plan view illustrating a display device according to one or more embodiments;

FIGS. 2 and 3 are schematic cross-sectional views illustrating a display device according to one or more embodiments;

FIG. 4 is a schematic block diagram illustrating a pixel circuit according to one or more embodiments;

FIGS. 5-10 are schematic diagrams illustrating a pixel circuit layer including a pixel circuit according to one or more embodiments;

FIGS. 11-15 are schematic cross-sectional views of process steps illustrating a method of manufacturing a display device according to one or more embodiments;

FIG. 16 is a schematic block diagram of an electronic device according to one or more embodiments; and

FIG. 17 shows schematic diagrams of various embodiments of an electronic device.

### DETAILED DESCRIPTION

As the present disclosure allows for various changes and numerous embodiments, particular embodiments will be illustrated in the drawings and described in detail in the written description. However, this is not necessarily intended to limit the present disclosure to particular modes of practice, and it is to be appreciated that all changes, equivalents, and substitutes that do not depart from the spirit and technical scope of the present disclosure are encompassed in the present disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the invention. Similarly, the second element could also be termed the first element. In the present disclosure, the singular forms are intended to include the plural forms as well, unless the context clearly indicates otherwise.

It will be further understood that the terms “comprise”, “comprise”, “have”, etc. when used in the present disclosure, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is disposed “on” a second part, the first part may be not only “directly on” the second part but a third part may intervene between them. In addition, when it is expressed that a first part such as a layer, a film, a region, or a plate is formed on a second part, the surface of the second part on which the first part is formed is not necessarily limited to an upper surface of the second part but may include other surfaces such as a side surface or a lower surface of the second part. To the contrary, in case that a first part such as a layer, a film, a region, or a plate is “under” a second part, the first part may be not only “directly under” the second part but a third part may intervene between them.

As used herein, an expression “at least one of” preceding a list of elements modifies the entire list of the elements and does not modify the individual elements of the list. For example, an expression, “at least one of a, b, and c” and “at least one of a, b, or c” should be understood as including only a, only b, only c, both a and b, both a and c, both b and c, or all of a, b, and c.

The disclosure relates to a display device, a method of manufacturing the display device, and an electronic device including the display device. Hereinafter, a display device, a method of manufacturing the display device, and an electronic device including the display device will be described with reference to the accompanying drawings.

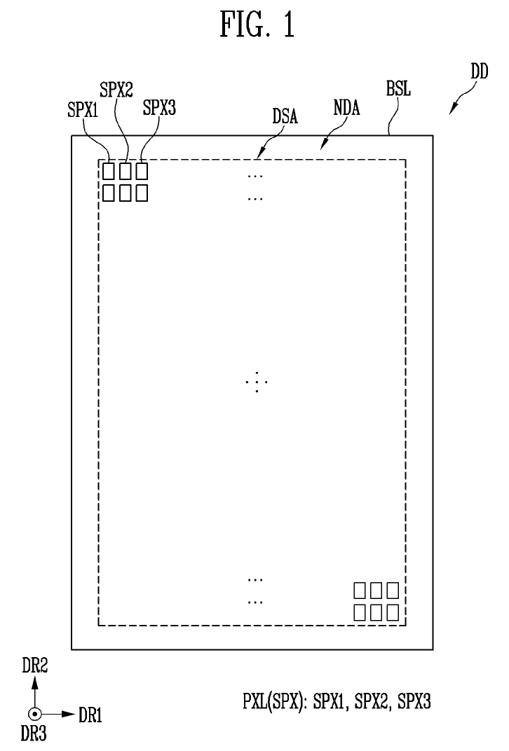

FIG. 1 is a schematic plan view illustrating a display device DD according to one or more embodiment.

Referring to FIG. 1, the display device DD may include a base layer BSL and a plurality of pixels PXL disposed on the base layer BSL. The display device DD may further include a driver circuit (e.g., a scan driver and a data driver), wiring lines, and pads for driving the pixels PXL.

The display device DD (or the base layer BSL) may include a display area DSA and a non-display area NDA. The non-display area NDA may refer to an area outside of the display area DSA. The non-display area NDA may surround at least a portion of the displayable area DSA. For example, the non-display area NDA may surround the entirety of the display area in plan view.

The base layer BSL may form a base surface of the display device DD. According to one or more embodiments, the base layer BSL may be a lower substrate for placing layers forming the display device DD. The base layer BSL may be a rigid or flexible substrate or film. For example, the base layer BSL may include at least one of a glass material, a silicone-based material, or polyimide. However, the disclosure is not limited thereto.

The term “plane” herein may be defined with respect to a plane on which the base layer BSL is disposed, in a direction extending in a first direction DR1 and a second direction DR2 which are each a horizontal direction. According to one or more embodiments, a third direction DR3, which is a vertical direction, may be a thickness direction of the base layer BSL, and the third direction DR3 may be an emission direction of the display device DD.

The display area DSA may refer to an area in which the pixels PXL are disposed. The non-display area NDA may refer to an area in which the pixels PXL are not disposed. The non-display area NDA may include a driver circuit, wiring lines, and pads which are connected to the pixels PXL of the display area DSA.

In the embodiments described herein, the pixels PXL (or sub-pixels SPX) may be disposed according to a stripe or Pentile^{TM} array structure, but the disclosure is not limited thereto. Various other embodiments may be applied in the disclosure.

According to one or more embodiments, a pixel PXL (or sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. The first sub-pixel SPX1, the second sub-pixel SPX2, and the third sub-pixel SPX3 may form a pixel unit capable of emitting a light of various colors.

Each of the first sub-pixel SPX1, the second sub-pixel SPX2, and the third sub-pixel SPX3 may emit a single color of light.

For example, the first sub-pixel SPX1 may be a red pixel emitting a light of red (i.e., a first color), the second sub-pixel SPX2 may be a green pixel emitting a light of green (i.e., a second color), and the third sub-pixel SPX3 may be a blue pixel emitting a light of blue (i.e., a third color). The red pixel may emit a light in a wavelength band from 600 nm to 750 nm. The green pixel may emit a light in a wavelength band from 480 nm to 560 nm. The blue pixel may emit a light in a wavelength band from 370 nm to 460 nm.

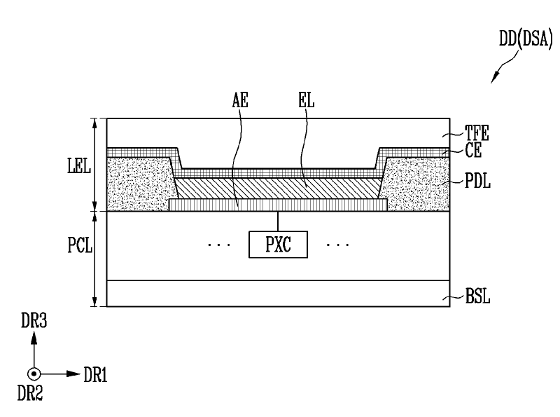

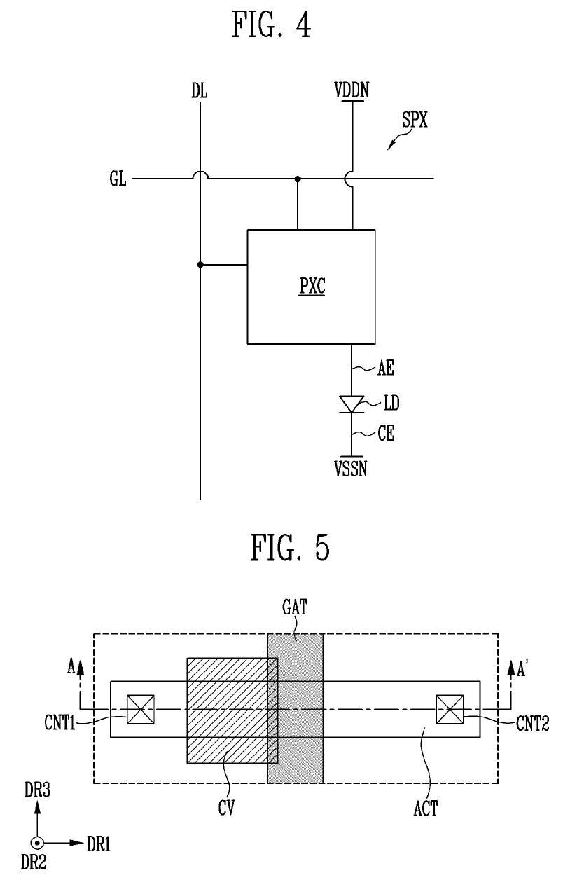

FIGS. 2 and 3 are schematic cross-sectional views illustrating a display device according to one or more embodiments. FIG. 3 illustrates a portion of the display device DD in the display area DSA. FIG. 4 is a schematic block diagram illustrating a pixel circuit according to one or more embodiments.

Referring to FIGS. 2-4, the display device DD may include a pixel circuit layer PCL and a light emitting element layer LEL. The display device DD may further include an upper layer UL.

The pixel circuit layer PCL may include the base layer BSL. The pixel circuit layer PCL may include a pixel circuit PXC. The pixel circuit layer PCL may be a backplane layer. The pixel circuit PXC may be formed on the base layer BSL and may drive the light emitting element LD.

The pixel circuit PXC may include circuit elements. The circuit elements may include driving transistors and switching transistors, and may include additional transistors and capacitors.

The light emitting element layer LEL may be disposed on the pixel circuit layer PCL. The light emitting layer LEL may include a plurality of light emitting elements LD. The light emitting element layer LEL may further include a pixel defining layer PDL and an encapsulation layer TFE.

A light emitting element LD may be electrically connected to the pixel circuit PXC. According to one or more embodiments, the light emitting element LD may include an organic light emitting diode (OLED) including an organic material. Alternatively or additionally, according to one or more embodiments, the light emitting element LD may include an inorganic light emitting diode including an inorganic material. However, the disclosure is not limited to a specific example.

The light emitting element LD may include an anode electrode AE, an emission structure EL, and a cathode electrode CE. According to one or more embodiments, the emission structure EL may be disposed in a region defined by the pixel defining layer PDL. For example, the emission structure may be surrounded by the pixel defining layer PDL in plan view. The pixel defining layer PDL may be adjacent to a periphery of the emission structure EL. A surface of the emission structure EL may be electrically connected to the anode electrode AE, and the other surface of the emission structure EL may be electrically connected to the cathode electrode CE. The anode electrode AE and the cathode electrode CE may each include one or more conductive materials.

The emission structure EL may include a plurality of layers. For example, the emission structure EL may include a plurality of emission structures including a hole transport layer, a light emitting layer (or a light generating layer), and an electron transport layer. Each of the layers forming the emission structure EL may include an organic material. According to one or more embodiments, each layer may further include a metal-containing compound or an inorganic layer such as a quantum dot.

The pixel defining layer PDL may be disposed on the pixel circuit layer PCL to define where the emission structure EL is disposed. The pixel defining layer PDL may include an organic material or an inorganic material. For example, the pixel defining layer PDL may include a plurality of layers, each including an inorganic material. However, the disclosure is not limited thereto.

The encapsulation layer TFE may be disposed on the light emitting element LD (e.g., the cathode electrode CE). The encapsulation layer TFE may offset a step difference generated by the light emitting element LD and the pixel defining layer PDL. The encapsulation layer TFE may include a plurality of insulating layers on the light emitting element LD. For example, the insulating layers may cover the light emitting element LD. According to one or more embodiments, the encapsulation layer TFE may include an inorganic layer and an organic layer. For example, the encapsulation layer TFE may have a structure including a first inorganic layer, an organic layer, and a second inorganic layer disposed sequentially. However, the disclosure is not limited thereto. According to one or more embodiments, the encapsulation layer TFE may be a thin-film encapsulation layer.

The upper layer UL may be disposed on the light emitting layer LEL. The upper layer UL may include various layers which transmit light, such as a cover window. According to one or more embodiments, the upper layer UL may include a color filter, a lens array layer, a polarization layer, etc. However, the disclosure is not limited to a specific example.

According to one or more embodiments, a sub-pixel SPX may include the pixel circuit PXC and the light emitting element LD.

The light emitting element LD may be electrically connected between a first power supply voltage node VDDN and a second power supply voltage node VSSN. The first power supply voltage node VDDN may be electrically connected to a first power line and receive a first power supply voltage, and the second power supply voltage node VSSN may be electrically connected to a second power line and receive a second power supply voltage. The first power supply voltage may have a higher voltage level than the second power supply voltage.

The anode electrode AE of the light emitting element LD may be electrically connected to the first power supply voltage node VDDN through the pixel circuit PXC. For example, the anode electrode AE may be electrically connected to the first power supply voltage node VDDN through one or more transistors included in the pixel circuit PXC. The cathode electrode CE of the light emitting element LD may be electrically connected to the second supply voltage node VSSN. The light emitting element LD emits light in response to a current flowing from the anode electrode AE to the cathode electrode CE.

The pixel circuit PXC may be electrically connected to a gate line GL and a data line DL. The pixel circuit PXC may control the light emitting element LD in response to a gate signal received via the gate line GL, and may cause the light emitting element LD to emit light in response to a data signal received via the data line DL.

In embodiments, the transistors of the pixel circuit PXC may include field effect transistors (FET). The transistors of the pixel circuit PXC may include metal oxide silicon field effect transistors (MOSFET). The transistors of the pixel circuit PXC may include P-type transistors and/or N-type transistors. For convenience of explanation, embodiments will be described herein based on some of the transistors of the pixel circuit PXC being P-type transistors.

Referring to FIGS. 5-10, the pixel circuit PXC and neighboring structures according to one or more embodiments will be described. For convenience of explanation, content which may be redundant with the foregoing will be briefly described and not repeated.

FIGS. 5-10 are schematic diagrams illustrating a pixel circuit layer including a pixel circuit according to one or more embodiments. For convenience of explanation, FIGS. 5-10 schematically illustrate only the pixel circuit layer PCL of the display device DD. An active layer ACT and neighboring structures as shown in FIGS. 5-10 may form at least some of the transistors of the pixel circuit PXC.

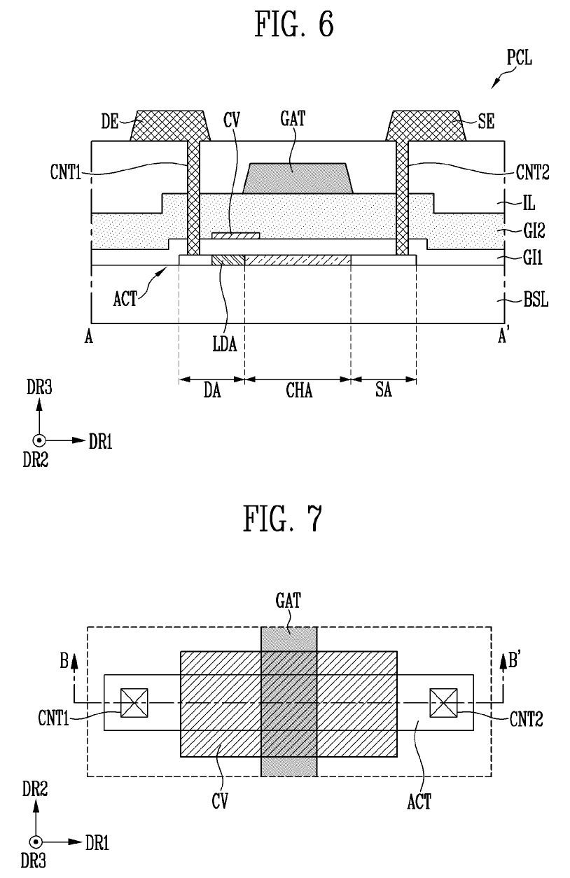

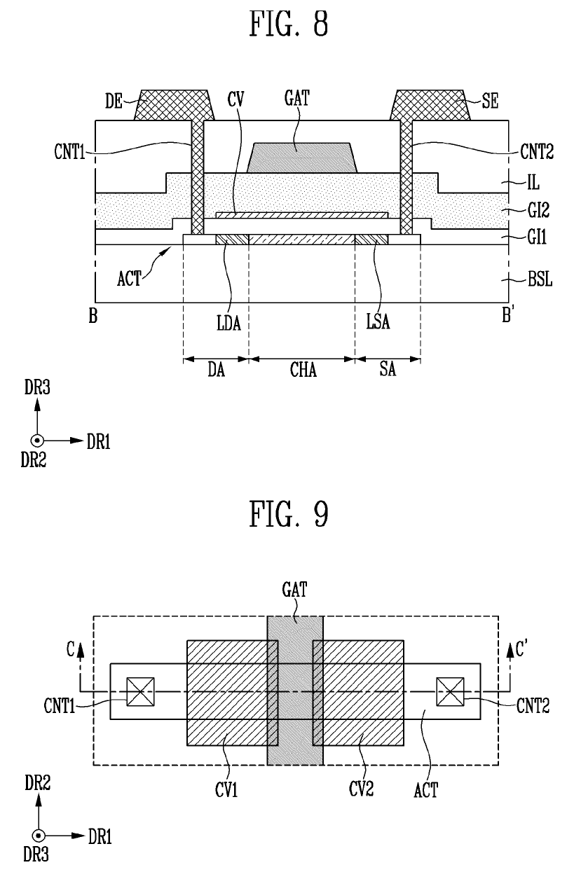

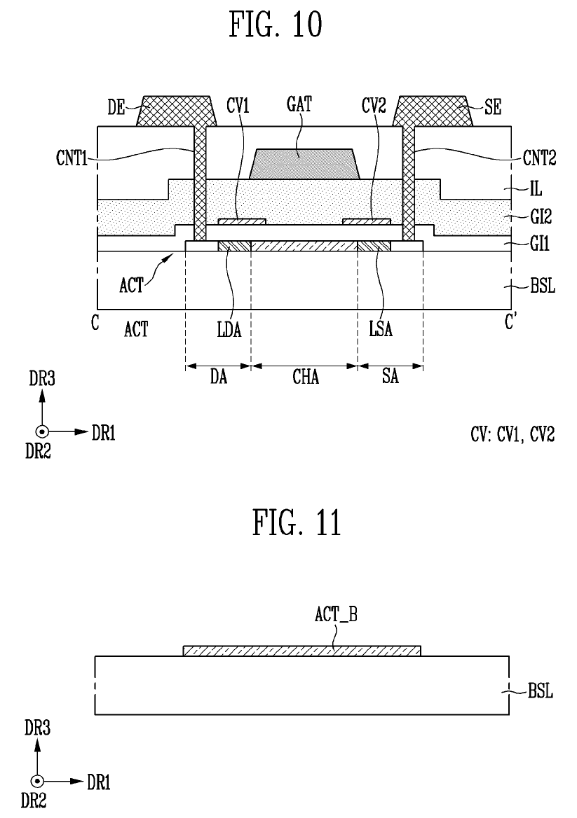

FIG. 5 is a schematic plan view illustrating a pixel circuit layer according to one or more embodiments. FIG. 6 is a schematic cross-sectional view taken along line A-A’ of FIG. 5. FIG. 7 is a schematic plan view illustrating a pixel circuit layer according to one or more other embodiments. FIG. 8 is a schematic cross-sectional view taken along line B-B’ of FIG. 7. FIG. 9 is a schematic plan view illustrating a pixel circuit layer according to one or more other embodiments. FIG. 10 is a schematic cross-sectional view taken along line C-C’ of FIG. 9.

First, with reference to FIG. 5 and 6, the pixel circuit layer PCL including the pixel circuit PXC according to one or more embodiments will be described.

According to one or more embodiments, the pixel circuit layer PCL may include the active layer ACT, a first gate insulating layer GI1, a cover layer CV, a second gate insulating layer GI2, a gate layer GAT, an interlayer insulating layer IL, a first contact portion CNT1, a second contact portion CNT2, a drain electrode DE, and a source electrode SE.

The active layer ACT may be disposed on the base layer BSL. A buffer layer which includes one or more inorganic materials may be further interposed between the base layer BSL and the active layer active contact according to one or more embodiments.

The active layer ACT may include an amorphous silicon semiconductor, monocrystalline silicon, polycrystalline silicon, or oxide semiconductor.

The active layer ACT may form at least a portion of the circuit elements of the pixel circuit PXC. For example, the active layer ACT may form at least one of the driving transistors, switching transistors, and additional transistors of the pixel circuit PXC.

The active layer ACT may include a source region SA, a channel region CHA, and a drain region DA.

The source region SA and the drain region DA may be doped with dopants. For example, when the transistor formed by the active layer ACT is a p-type metal-oxide-semiconductor (PMOS), the source region SA and the drain region DA may be provided with p-type dopants.

The channel region CHA may be formed between the source region SA and the drain region DA, and may be a region substantially undoped with dopants.

According to one or more embodiments, the drain region DA may include a low-concentration drain region LDA.

The low-concentration drain region LDA may be overlapped by the cover layer CV in plan view or in the third direction DR3. The low-concentration drain area LDA may be formed based on the cover layer CV during the manufacturing process of the display device DD. Herein, overlapping between structural elements in plan view may refer to overlapping in the third direction DR3, and thus, overlapping in plan view and overlapping in the third direction DR3 are interchangeably used.

The low-concentration drain region LDA may be adjacent to the channel region CHA along a plane direction (e.g., a horizontal direction) in which the base layer BSL is disposed. For example, the low-concentration drain region LDA may be directly adjacent to the channel region CHA. A different portion of the drain region DA other than the low-concentration drain region LDA may be formed at a side of the low-concentration drain region LDA, and the channel region CHA may be formed at the other side of the low-concentration drain region LDA, in the first direction DR1.

The concentration of the dopant in the low-concentration drain region LDA may be less than the concentration of the dopant in a region outside the low-concentration drain region LDA in the drain region DA and greater than the concentration of the dopant in the channel region CHA if the channel region is doped with the dopant.

The low-concentration drain region LDA may mitigate a relatively sharp change in doping concentration between the drain region DA and the channel region CHA. Accordingly, the low-concentration drain region LDA may prevent an electric field from being concentrated between the drain region DA and the channel region CHA, and may reduce a risk of leakage current in the active layer ACT.

The low-density drain region LDA can reduce gate-induced drain leakage (GIDL) current which may be caused by a high electric field between the gate layer GAT and the drain region DA.

According to one or more embodiments, two or more insulating layers may be interposed between the active layer ACT and the gate layer GAT.

The first gate insulating layer GI1 may be disposed on the base layer BSL and the active layer ACT. The first gate insulating layer GI1 may be disposed on the active layer ACT. The first gate insulating layer GI1 may include various inorganic materials. According to one or more embodiments, the first gate insulating layer GI1 may be formed as a single layer or multiple layers.

The second gate insulating layer GI2 may be disposed on the cover layer CV and the first gate insulating layer GI1. The second gate insulating layer GI2 may be formed on the cover layer CV, for example. The second gate insulating layer GI2 may include various inorganic materials. According to one or more embodiments, the second gate insulating layer GI2 may be formed as a single layer or multiple layers.

The cover layer CV may be disposed on top of the first gate insulating layer GI1.

The cover layer CV may overlap the drain region DA in plan view. The cover layer CV may overlap the low-concentration drain region LDA in plan view. The cover layer CV may not overlap a portion of the drain region DA in plan view. The cover layer CV may overlap the entirety of the low-concentration drain region LDA in plan view.

The cover layer CV may be formed across the low-concentration drain region LDA and the channel region CHA in plan view. At least a portion of the cover layer CV may be overlapped by the gate layer GAT in a plan view. The cover layer CV may overlap at least a portion of the channel region CHA in plan view.

According to one or more embodiments, the cover layer CV may not overlap the source region SA.

The cover layer CV may be overlapped by one end of the gate layer GAT in the first direction DR1 and may not overlap with the other end of the gate layer GAT in the first direction DR1, in plan view.

The cover layer CV may be floated. The cover layer CV may have a floating state. For example, the cover layer CV may not be directly connected to other electrodes or wiring lines. The cover layer CV may form a floating capacitance between the drain region DA and the gate layer GAT. Accordingly, electrons may be more effectively trapped in a lower portion of the cover layer CV (e.g., a portion of the first gate insulating layer GI1 adjacent to the cover layer CV), and the gate-induced drain leakage current may be substantially reduced.

According to one or more embodiments, the cover layer CV may have an isolated shape (e.g., an island shape) in plan view. The cover layer CV may have a polygonal shape or a shape with a curvature (e.g., a circular or elliptical shape). However, the disclosure is not limited to any particular example.

According to one or more embodiments, the cover layer CV may have a thickness which is less than the first gate insulating layer GI1 and the second gate insulating layer GI2. Accordingly, as described below, the low-concentration drain region LDA may be suitably formed in some regions of the active layer ACT overlapped by the cover layer CV in plan view.

For example, the cover layer CV may have a thickness of 10 Å to 1000 Å. The first gate insulating layer GI1 may have a thickness, greater than that of the cover layer CV, which is selected in the range of 100 Å to 1500 Å. The second gate insulating layer GI2 may have a thickness, greater than that of the cover layer CV, selected in the range of 100 Å to 1000 Å.

The cover layer CV may be used to form the low-concentration drain region LDA in a portion of the drain region DA during the manufacturing process of the display device DD.

For example, when a doping process is performed to form the drain region DA, a portion of the drain region DA doped with a higher concentration of dopant than the low-concentration drain region LDA may be formed in the area not overlapped by the cover layer CV, and the low-concentration drain region LDA may be formed in the area overlapped by the cover layer CV, in plan view.

As described above, the low-concentration drain region LDA may reduce the risk of leakage current in the active layer ACT.

The cover layer CV may include a material through which the dopant is permeable. For example, the cover layer CV may include an amorphous silicon material. During the doping process, the region overlapped by the cover layer CV in the third direction DR3 may be doped with a relatively low concentration of dopant, and the low-concentration drain region LDA may be formed. According to one or more embodiments, the cover layer CV may include an amorphous silicon material doped to be conductive.

According to one or more embodiments, as the cover layer CV is formed, electron trapping may occur to a greater extent on the lower portion of the cover layer CV, thereby reducing the gate-induced drain leakage current. The leakage current may be substantially reduced due to the low-concentration drain region LDA formed based on the cover layer CV.

The risk of the display quality being compromised due to the leakage current is reduced, and the display device DD with improved display performance and electrical signal reliability may be provided.

For example, in order to drive a plurality of pixels (PXL) in the display area DSA, a method may be used in which a pixel PXL emits light immediately even when a gate voltage is applied to the switching transistors in the pixel circuit PXC of each pixel PXL, and a method may also be used in which the pixels PXL emit light simultaneously after a gate voltage is applied to all of the switching transistors of the pixels PXL formed in a plurality of rows.

Experimentally, when these methods are used, there may be a greater concern that the display quality may be impaired, such as mura effects of the display area DSA, when an off current or leakage current is generated in each switching transistor.

However, in an embodiment where the cover layer CV is provided on the active layer ACT, the possibility of leakage current being generated in the circuit elements of the pixel PXL may be reduced, thereby reducing the aforementioned risk.

The gate layer GAT may be disposed on the second gate insulating layer GI2. The gate layer GAT may overlap the channel region CHA in plan view. The gate layer GAT may be electrically connected to the gate line GL and may receive a gate voltage to turn on the transistor.

The gate layer GAT may overlap the cover layer CV in plan view. For example, the gate layer GAT may overlap one end of the cover layer CV in the first direction DR1 and may not overlap with the other end of the cover layer CV in the first direction DR1, in plan view.

The gate layer GAT can include a variety of conductive materials (e.g., various metals, etc.). The gate layer GAT may form a gate electrode of a transistor (e.g., a switching transistor) formed by the active layer ACT.

The interlayer insulating layer IL may cover at least a portion of the gate layer GAT. The interlayer insulating layer IL may be disposed on the gate layer GAT and the second gate insulating layer GI2. The interlayer insulating layer IL may include an inorganic material or an organic material.

The drain electrode DE and the source electrode SE may be disposed on the interlayer insulating layer IL.

The drain electrode DE may be electrically connected to the active layer ACT via the first contact portion CNT1 which penetrates the interlayer insulating layer IL, and the first and second gate insulating layers GI and GI2. The first contact CNT1 may be connected to a region outside the low-concentration drain region LDA of the drain region DA.

The source electrode SE may be electrically connected to the active layer ACT via the second contact portion CNT2 which penetrates the interlayer insulating layer IL and the first and second gate insulating layers GI1 and GI2. The second contact CNT2 may be connected to the source region SA.

Herebelow, with reference to FIGS. 7 and 8, the pixel circuit layer PCL including the pixel circuit PXC according to one or more other embodiments will be described. For ease of explanation, redundant content with the previously described embodiments will be briefly described or omitted.

The pixel circuit layer PCL according to this embodiment differs from the pixel circuit layer PCL according to the previously described embodiment in which the cover layer CV is disposed across the drain region DA, the channel region CHA, and the source region SA in plan view.

The cover layer CV may overlap the drain region DA, the channel region CHA, and the source region SA in plan view. The cover layer CV may overlap each of the an end and the other end of the gate layer GAT in the first direction DR1, in plan view.

The source region SA may include a lower-concentration source region LSA. The cover layer CV may overlap the drain region DA to form the low-concentration drain region LDA, and may overlap with the source region SA to form the lower-concentration source region LSA.

The lower-concentration source region LSA may be a portion doped with a lower concentration of dopant than other portions of the source region SA. According to one or more embodiments, as the portion of the cover layer CV overlaps the source region SA during the doping process to form the source region SA, the dopant may be provided in a lower concentration in some areas. Accordingly, the lower-concentration source region LSA may be formed in a portion of the source region SA.

In this embodiment, the cover layer CV, the lower-concentration source region LSA, and the low-concentration drain region LDA may also reduce the risk of leakage current and the like.

Herebelow, with reference to FIGS. 9 and 10, the pixel circuit layer PCL including the pixel circuit PXC according to one or more other embodiments will be described. For ease of explanation, redundant content with the previously described embodiment will be briefly described or omitted.

The pixel circuit layer PCL according to this embodiment differs from the pixel circuit layer PCL according to the previously described embodiment in that the cover layer CV includes a first cover layer CV1 and a second cover layer CV2 spaced apart from each other.

The first cover layer CV1 may have substantially the same structural features as the cover layer CV described above with reference to FIGS. 5 and 6. The second cover layer CV2 may overlap the source region SA in plan view, and may form the lower-concentration source region LSA.

The first cover layer CV1 and the second cover layer CV2 may be formed in the same process.

In this embodiment, the first and second cover layers CV1 and CV2, the lower-concentration source region LSA, and the low-concentration drain region LDA may also reduce the risk of leakage current and the like.

Referring to FIGS. 11-15, a manufacturing method of the display device DD according to one or more embodiments will be described. For convenience of explanation, content which may overlap with the foregoing will be briefly described and not repeated.

FIGS. 11-15 are schematic cross-sectional views of process steps illustrating a manufacturing method of a display device according to one or more embodiments. For ease of explanation, FIGS. 11-15 schematically illustrate cross-sectional structures of the pixel circuit layer PCL as described above with reference to FIG. 6 at respective process steps.

Referring to FIG. 11, a base active layer ACT_B may be patterned on the base layer BSL. For example, depending on the material of the active layer ACT to be provided, an appropriate process may be performed. For example, when the active layer ACT includes a polycrystalline silicon semiconductor, a crystallization process or the like may be performed in this process.

According to one or more embodiments, a conductive layer or an insulating layer on the base layer BSL may be formed based on conventional processes for manufacturing a semiconductor device. For example, the conductive layer or the insulating layer on the base layer BSL may be formed by a photolithography process, may be etched by various methods (wet etch, dry etch, etc.), and may be deposited by various methods (sputtering, chemical vapor deposition, etc.). The disclosure is not necessarily limited to any particular example.

According to one or more embodiments, a buffer layer may be disposed on the base layer BSL before the base active layer ACT_B is patterned.

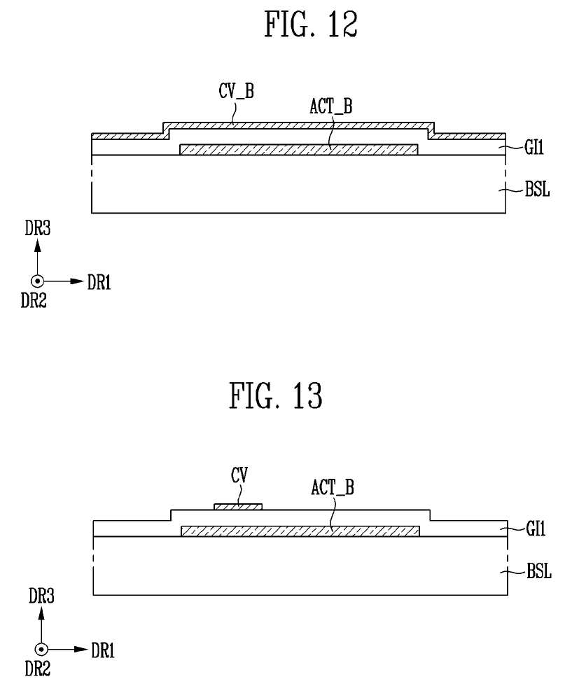

Referring to FIG. 12, the first gate insulating layer GI1 may be formed on the base active layer ACT_B, and a base cover layer CV_B may be formed on the first gate insulating layer GI1.

In this process, the first gate insulating layer GI1 may cover the entirety of the base active layer ACT_B. The base cover layer CV_B may be a layer for obtaining the cover layer CV, and may overlap at least a portion of the base active layer ACT_B in plan view.

In this process, according to one or more embodiments, the base cover layer CV_B including an amorphous silicon material may be disposed. For example, the base cover layer CV_B may be formed by a chemical vapor deposition (CVD) method.

Referring to FIG. 13, at least a portion of the base cover layer CV_B may be removed (e.g., etched), and the cover layer CV may be obtained.

In this process, the cover layer CV may be patterned at a location where the low-concentration drain region LDA is formed during a subsequent process.

According to one or more embodiments, referring to FIGS. 7 and 8, the cover layer CV may be patterned across a region where the source region SA, the channel region CHA, and the drain region DA are formed, in plan view.

Referring to FIGS. 9 and 10, according to one or more embodiments, the cover layer CV may be patterned to include the first cover layer CV1 overlapping a location where the drain region DA is formed and the second cover layer CV2 overlapping a location where the source region SA is formed, in plan view.

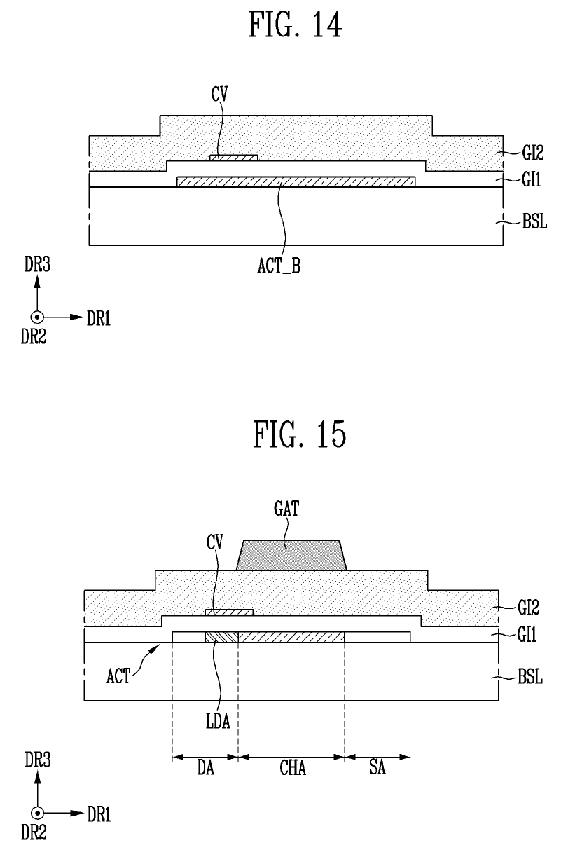

Referring to FIG. 14, the second gate insulating layer GI2 may be formed on the cover layer CV.

In this process, the second gate insulating layer GI2 may cover the entirety of the cover layer CV. Accordingly, a plurality of gate isolation structures for the active layer ACT according to one or more embodiments may be formed.

Referring to FIG. 15, the gate layer GAT may be patterned on the second gate insulating layer GI2, and a doping process may proceed.

In this process, after the gate layer GAT is patterned, a doping process may be carried out, whereby the drain region DA and the source region SA may be formed to obtain the active layer ACT.

In this process, since the cover layer CV overlaps a portion of the drain region DA in the third direction DR3, the low-concentration drain region LDA may be formed in some regions of the active layer ACT overlapped by the cover layer CV. For example, the dopant may be provided in a higher amount in an areas not overlapped by the cover layer CV compared to areas overlapped by the cover layer, in the third direction DR3. For example, since the cover layer CV includes an amorphous silicon material, a predetermined amount of the dopant may be permeable to the cover layer CV.

Subsequently, according to one or more embodiments, the interlayer insulating layer IL may be disposed on the gate layer GAT, and the source electrode SE and the drain electrode DE may be formed to provide the pixel circuit layer PCL. Further, the light emitting element layer LEL including the light emitting element LD or the like may be disposed on the pixel circuit layer PCL, the upper layer UL including various layers may be disposed on the light emitting element layer LEL, and the display device DD according to one or more embodiments may be provided.

As described above, the display device DD may include a circuit element having a reduced risk of leakage current due to the cover layer CV and the resulting low-concentration drain region LDA, and the display device DD may be disposed to have excellent display quality.

The display device DD according to one or more embodiments may be applicable to various types of electronic devices. In an embodiment, an electronic device 10 may include the above-described display device DD and may further include other modules or devices having additional functions in addition to the display device DD.

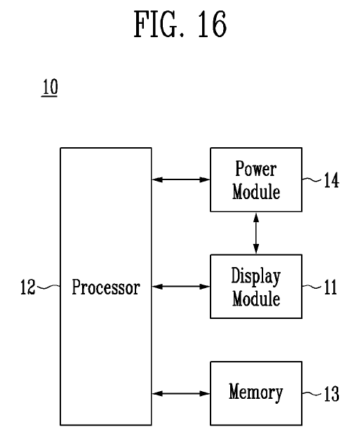

FIG. 16 is a schematic block diagram of an electronic device according to one or more embodiments. Referring to FIG. 16, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. The processor 12 may be electrically connected to the display module 11.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply, such as a power adapter or a battery device, and a power converter. The power converter may convert power supplied by the power supply and generate power to operate the electronic device 10.

At least one of the above-described components of the electronic device 10 may be included in the display device DD according to the above-described embodiments. In terms of functionality, some of the structural elements forming the electronic device 10 may be included in the display device DD and others may be provided separately from the display device DD. For example, the display module 11 may be comprised in the display device DD, whereas the processor 12, the memory 13, and the power module 14 may not be included in the display device DD and instead be provided separately in the electronic device 10.

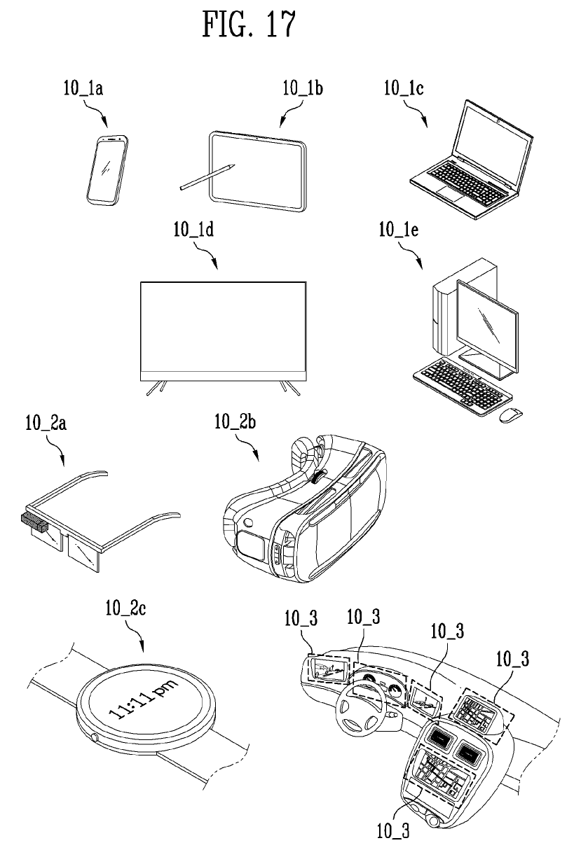

FIG. 17 shows schematic diagrams of various embodiments of an electronic device.

Referring to FIG. 17, various types of electronic devices to which embodiments of the display device DD are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

According to one or more embodiments of the present disclosure, a display device, a method of manufacturing the display device, and an electronic device including the display device may be provided, in which the risk of leakage current being generated can be reduced, and the risk of the display quality being impaired due to the leakage current can be reduced accordingly.

According to one or more embodiments of the present disclosure, a display device, a method of manufacturing the display device, and an electronic device including the display device may be provided, in which a display quality can be improved.

While the disclosure has been particularly shown and described with reference to embodiments thereof, it will be understood by those of ordinary skill in the art that various changes in form and detail may be made therein without departing from the spirit or scope of the disclosure as defined by the following claims.

Accordingly, the technical scope of the disclosure should be defined not by the detailed description of the specification, but by the claims.

What is claimed is:

1. A display device, comprising:
an active layer on a base layer, the active layer comprising a source region, a drain region, and a channel region;
a cover layer above the active layer; and
a gate layer above the channel region,
wherein the drain region comprises a first region overlapped by the cover layer and a second region not overlapped by the cover layer, in plan view, and
wherein the first region has a lower dopant concentration than the second region.

2. The display device of claim 1, wherein the cover layer comprises a material that is permeable to a dopant doped into the drain region.

3. The display device of claim 2, wherein the cover layer comprises an amorphous silicon material.

4. The display device of claim 1, wherein the cover layer is formed across the first region and the channel region in plan view.

5. The display device of claim 4, wherein the cover layer overlaps the first region entirely in plan view.

6. The display device of claim 1, wherein the cover layer has a floating state.

7. The display device of claim 1, further comprising at least one gate insulating layer,
wherein the cover layer is in the at least one gate insulating layer.

8. The display device of claim 1, further comprising:
a first gate insulating layer on the active layer; and
a second gate insulating layer on the cover layer and the first gate insulating layer,
wherein the cover layer has a thickness less than the first gate insulating layer and the second gate insulating layer, and has a thickness of 10 Å to 1000 Å.

9. The display device of claim 1, wherein the second region is formed at a side of the first region, and the channel region is formed at another side of the first region.

10. The display device of claim 9, wherein the cover layer does not overlap the source region in plan view.

11. The display device of claim 1, wherein the cover layer is disposed across the drain region, the channel region, and the source region in plan view, and
wherein the source region comprises a third region overlapped by the cover layer and a fourth region not overlapped by the cover layer, in plan view.

12. The display device of claim 1, wherein the cover layer comprises a first cover layer overlapping the first region and a second cover layer overlapping the source region in plan view.

13. The display device of claim 12, wherein the source region comprises a third region overlapped by the second cover layer and a fourth region not overlapped by the second cover layer, in plan view, and
wherein the third region has a lower dopant concentration than the fourth region.

14. A display device, comprising:
an active layer on a base layer, the active layer comprising a source region, a drain region, and a channel region;
a gate layer above the channel region,
wherein the drain region comprises a first region and a second region,
wherein the first region is between the second region and the channel region
wherein the first region has a lower dopant concentration than the second region.

15. A method of manufacturing a display device, the method comprising:
patterning a base active layer on a base layer;
patterning a cover layer above the base active layer;
patterning a gate layer above the base active layer and the cover layer; and
obtaining an active layer by forming a source region, a drain region, and a channel region on the base active layer,
wherein the cover layer comprises an amorphous silicon material.

16. The method of claim 15, wherein the obtaining the active layer comprises performing a doping process on the base active layer, and
wherein the performing the doping process comprises forming a first region in the drain region overlapped by the cover layer.

17. The method of claim 16, wherein the patterning the cover layer comprises patterning the cover layer at a location below which the first region is formed.

18. The method of claim 16, wherein the patterning the cover layer comprises patterning the cover layer across an area below which the source region, the channel region, and the drain region are formed, in plan view.

19. The method of claim 16, wherein the patterning the cover layer comprises patterning a first cover layer overlapping the drain region and a second cover layer overlapping the source region in plan view.

20. An electronic device, comprising:
a processor;
a display module configured to be electrically connected to the processor, the display module comprising the display device of claim 1; and
a power module configured to provide power to the display module.
